(19) United States
(12) Patent Application Publication
(10) Pub. No.: US 2012/0009355 A1
(43) Pub. Date: Jan. 12, 2012

(54) METHOD AND APPARATUS FOR STABILIZING A COATING

(75) Inventors: Steven M. Gasworth, Novi, MI (US); Michael R. Haag, Dearborn, MI (US); Scott Corneillie, Chesterfield, MI (US)

(73) Assignee: EXATEC, LLC, Wixom, MI (US)

(21) Appl. No.: 13/234,682

(22) Filed: Sep. 16, 2011

Related U.S. Application Data
(62) Division of application No. 11/954,766, filed on Dec. 12, 2007.
(60) Provisional application No. 60/882,314, filed on Dec. 28, 2006.

(51) Int. Cl. C23C 16/54; H05H 1/24

(52) U.S. Cl. 427/569; 427/255.28; 427/248.1

(57) ABSTRACT

A method and apparatus for stabilizing an incidental coating in a substrate coating apparatus is provided. The method includes defining interior surfaces of a coating zone in the substrate coating apparatus. The method may include preheating interior surfaces to a local preheat temperature that is approximately equal to a local coating temperature attained by the surfaces during coating of a substrate, at least partially defining the interior surfaces with a compliant fabric, or at least partially defining the interior surfaces with a compliant fabric and preheating the interior surfaces.

### CROSS REFERENCE TO RELATED APPLICATION

The present application is a Divisional of U.S. patent application Ser. No. 11/954,766, filed Dec. 12, 2007, which is a Non-Provisional Application, and claims the benefit of U.S. Provisional Patent Application No. 60/882,314, filed Dec. 28, 2006, the contents each of which are incorporated herein by reference thereto.

### BACKGROUND OF THE INVENTION

The present invention relates generally to coating processes. More specifically, it relates to methods and apparatuses for stabilizing an incidental coating on the interior surfaces of a substrate coating apparatus.

During continuous or batch coating of substrates within a substrate coating apparatus, it has been observed that the substrates may become damaged or acquire defects due to the ejection of particles from the incidental coating that is produced on the interior surfaces of the substrate coating apparatus, specifically, those surfaces within the substrate coating zone. The ejection of the particles occurs as a result of stresses that develop within the incidental coating itself. These stresses result from various factors including differential thermal expansion and contraction of the incidental coating, relative to the surfaces to which they are adhered, during temperature changes of these surfaces. Moreover, as the coating process continues, the thickness of the incidental coating increases, thereby increasing the magnitude of the stress within the coating.

If the stresses in the incidental coating were to be stabilized or inhibited, this would decrease the frequency of substrates being produced with defects and would reduce the cleaning frequency of the interior surfaces of the coating zone, thereby enhancing utilization of the substrate coating apparatus.

### BRIEF SUMMARY OF THE INVENTION

In addressing the drawbacks and limitations of the known technology, a method and apparatus for stabilizing an incidental coating on one or more interior surfaces of a substrate coating apparatus is provided. The specific interior surfaces are those surfaces present within the substrate coating zone of the apparatus, which may be the actual wall surfaces, surfaces of elements or structures in the coating zone, or those of a compliant fabric located over such surfaces.

In one aspect of the invention, the method includes heating the interior surfaces to a local preheat temperature prior to introduction of substrates into the substrate coating zone. The local preheat temperature is selected such that it approximately equals the temperature that will be attained by the interior surfaces during actual coating of the substrates.

In another aspect, the invention provides for use of a compliant fabric to at least partially define the interior surfaces of the coating zone. As such, the compliance of the fabric, along with the increased coatable surface area of the fabric relative to a smooth rigid surface, inhibits the ejection of particles from the incidental coating.

One further aspect of the invention involves both at least partially defining the interior surfaces of the coating zone with a compliant fabric and preheating the interior surfaces to the local preheat temperature.

The various embodiments of the present invention inhibit the development of undesirably high stresses within the incidental coating that forms on the interior surfaces of the coating zone. Consequently, the ejection of particles from the incidental coating during the coating process is also inhibited. In doing this, the present invention decreases or prevents the occurrence of defects in the coated substrate.

### BRIEF DESCRIPTION OF THE DRAWINGS

The various embodiments of the present invention will hereinafter be described in conjunction with the appended drawings, which are provided to illustrate and not to limit the invention, wherein like designations denote like elements, and in which:

FIG. 1 is a schematic, plan view of a substrate coating apparatus, in accordance with an embodiment of the present invention;

FIG. 2 is a schematic, plan view of the substrate coating zone seen in FIG. 1;

FIG. 3A illustrates a front view of a semi-rigid backing, in accordance with an exemplary embodiment of the present invention;

FIG. 3B illustrates a side view of a compliant fabric attached to the semi-rigid backing, in accordance with the embodiment of the present invention;

FIG. 3C illustrates a front view of the compliant fabric attached to the semi-rigid backing, in accordance with the embodiment of the present invention; and

FIG. 4 is a flowchart of a method for stabilizing an incidental coating on the interior surfaces of a substrate coating apparatus, in accordance with the principles of the present invention.

### DETAILED DESCRIPTION OF THE INVENTION

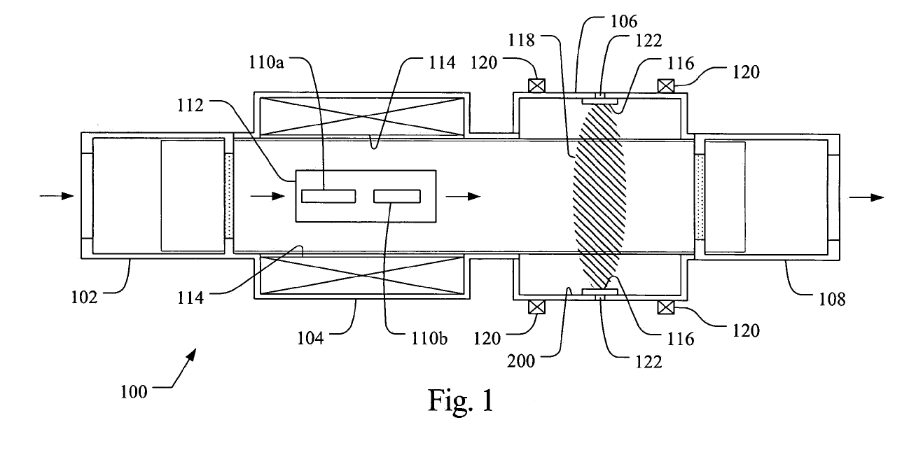

Referring now to the drawings, a substrate coating apparatus 100, in accordance with the principles of the present invention, is schematically shown in FIG. 1. The substrate coating apparatus 100 includes various stations or zones, such as a load lock 102, a substrate heating zone 104, one or more substrate coating zones 106, and an unload lock 108, all of which are connected in series and in an airtight manner. As such, the various stations and zones may be evacuated by a plurality of pumps (not shown) to maintain a suitable vacuum pressure that is conducive to the coating process.

The substrate coating apparatus 100 is preferably used to coat a plurality of substrates 110 (two substrates 110a, 110b being shown) as the substrates 110 are continuously moved through the apparatus 100. As those skilled in the art will appreciate, the present invention is equally applicable to a substrate coating apparatus 100 that performs the batch coating, instead of continuous coating, of substrates 110. Additionally, the coating apparatus 100 may employ any one of a number of coating processes, including, without limitation, chemical vapor deposition, plasma enhanced chemical vapor deposition and physical vapor deposition.

The substrates themselves may be formed from a wide variety of materials. In an exemplary embodiment, the substrates 110 are made of a thermoplastic material. Such materials include, but are not limited to, polyvinylalcohol, polyvinylacetal, polyvinylacetate, polyethylene, polypropylene, polystyrene, polyamide, polyimide and polyvinylchloride. Other suitable materials for the substrates 110 include polycarbonate resins, polyestercarbonates, acrylic polymers, polyesters, polyurethanes, and the like. Further examples of materials from which the substrates 110 may be made of include ceramic, glass, metal or a semiconductor. Generally, the invention has utility for any substrate 110 that would be affected by a particles being ejected from the interior surfaces of the coating zone 106 during coating.

The substrates 110 may be formed by a variety of techniques, depending on their construction material. Such techniques include, without limitation, injection molding, cold forming, vacuum forming, extrusion, blow molding, transfer molding, compression molding, and thermal forming. Additionally, the substrates 110 may be curved, flat, rigid or flexible, in nature.

In utilizing the apparatus 100, the substrates 110 are placed on a substrate carrier 112, which may be a rack, hanger or other device. Such devices are known in the industry and, therefore, are not further described herein. The substrate carrier 112 enters load lock 102 and, in the load lock 102 or prior thereto, is engaged by a conveyor that transports the carrier 112 and substrates 110 through the coating apparatus 100. Obviously, any mechanism suitable for transporting the carrier 112 and substrates 110 through the coating apparatus 100 may be employed.

Once transferred into the substrate heating zone 104, the substrates 110 are heated to a temperature suitable for coating of the substrates 110. To achieve this, the substrate heating zone 104 includes heating units 114, two being shown. The heating units 114 are located within or outside of, at or along the side walls of the substrate heating zone 104 or where dictated by the overall design of the apparatus 100. Various types of heating units 114 may be employed and include, but are not limited to, infrared heaters, microwave heaters, resistance heaters, non-reactive plasma plumes and the like.

After traveling through the substrate heating zone 104, the substrate carrier 112 enters the substrate coating zone 106, where a coating is deposited on the substrates 110. Once the substrates 110 have been coated, they are then transferred to the unload lock 108, where they are released from the coating apparatus 100.

While a variety of coating methodologies and procedures may be employed with the present invention, as illustrated the substrate coating zone 106 includes a series of expanding thermal plasma (ETP) source arrays 116, which may be located in pairs opposite one another. The ETP source arrays 116 are mounted on their own ports 122 or to a common manifold located on the side walls of the substrate coating zone 106.

Each of the ETP source arrays 116 is preferably fed with an inert gas that becomes partially ionized and which issues from the array 116 as a plasma plume, illustrated as combined or common plasma plume 118, into the substrate coating zone 106. Examples of inert gases that may be utilized with the coating apparatus 100 include, but are not limited to, argon, helium, neon and the like.

An oxidizing gas and a coating reagent are also injected from gas and reagent injection manifolds (not shown), respectively. The oxidizing gas and coating reagent, injected in vapor form, diffuse into the plasma plume 118, which expands into the substrate coating zone 106 and is directed towards the substrates 110 being conveyed therethrough. Examples of oxidizing gases include, but are not limited to, oxygen and nitrous oxide, or any combination thereof. Examples of coating reagents include, but are not limited to, organosilicons such as decamethylcyclopentasiloxane (D5), vinyltrimethylsilane (VTMS), dimethyldimethoxysilane (DMDMS), octamethylcyclotetrasiloxane (D4), tetramethyldisiloxane (TMDSO), tetramethyltetravinylcyclotetrasiloxane (V-D4), hexamethyldisiloxane (HMDSO) and the like.

The substrate coating zone 106 further includes heating units 120 located and employed to preheat interior surfaces 200 of the substrate coating zone 106 prior to the introduction of the substrates 110 into the zone 106. Preferably, the local preheat temperature is substantially equal to the local temperature attained by the interior surfaces 200 during the actual coating of the substrates 110. To determine when the local preheat temperature has been achieved, temperature measurement instruments (not shown), such as thermocouples, optical pyrometers, etc., are provided in conjunction with the coating zone 106.

As previously noted, the interior surfaces 200 may include one or more interior walls of substrate coating zone 106. The interior surfaces may also include, in part, the surfaces of various elements and structures that are located within substrate coating zone 106 during actual coating. These elements and structures (not shown) may include, for example, gas injection manifolds, reagent injection manifolds, supports for the same and other structures. Additionally, the interior surfaces 200 may be defined, at least in part, by a compliant fabric 204.

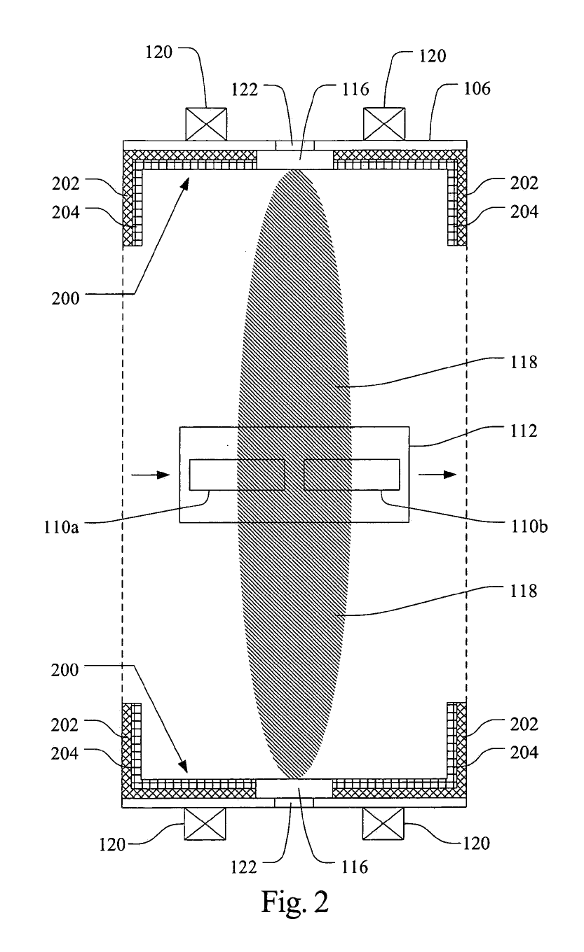

As detailed in FIG. 2, the substrate coating zone 106 includes a pair of opposed ETP source arrays 116 and heating units 120 (four such units being shown). The coating zone 106 has interior surfaces 200 that may, at least in part, be defined by a compliant fabric 204 attached to a semi-rigid backing 202. In one embodiment, the compliant fabric 204 is attached to semi-rigid backing 202 by suitable means, such as by wire stitches, clips and the like. Alternatively, the compliant fabric 204 may be directly attached to the interior walls of coating zone 106. As such, the compliant fabric 204, with or without the semi-rigid backing 202, may be periodically removed from substrate coating zone 106 for the performance of maintenance operations.

The attaching of the compliant fabric 204 to the semi rigid backing 202 holds the compliant fabric 204 securely during deposition of the coating on the substrates 110 and also facilitates the carrying out of maintenance, such as the removing of the incidental coating that gets deposited on the interior surfaces of the coating zone 106. As such, the incidental coating may be removed from the compliant fabric 204 or the compliant fabric 204 may be replaced.

It may be noted that the compliant fabric 204 is sufficiently flexible to allow for the substantial relaxation of any coating stresses that develop within the incidental coating deposited on the compliant fabric 204. Further, in that the compliant fabric 204 is made up of a series of fibers or strands, the actual surface of the compliant fabric 204 has a textured characteristic that provides a larger coatable surface area than that provided by a conventional planar wall of equal lateral extent. As a result, the thickness of the coating deposited on the compliant fabric 204 increases at comparatively slower rate. Since the coating stress tends to increase with the coating thickness, the development of any coating stress is further inhibited or retarded. From the above it is seen that the flexibility and the increased coatable surface area of the compliant fabric 204 operate to minimize the ejection of particles from the incidental coating since the development of any coating stress is substantially inhibited.

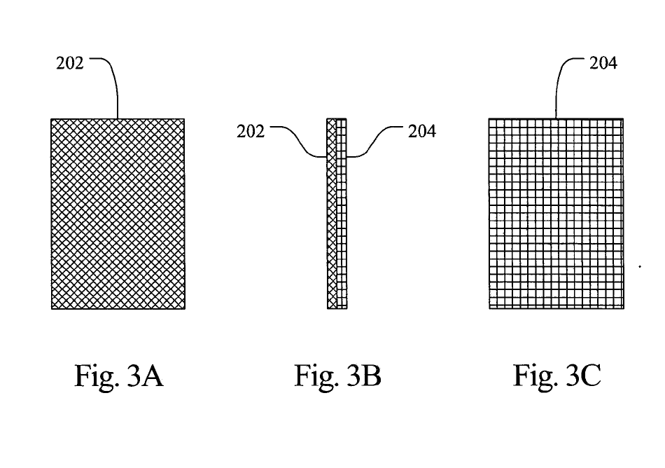

FIG. 3A illustrates a front view of the semi-rigid backing 202, in accordance with an exemplary embodiment of the present invention. Examples of the semi-rigid backing 202 include, but are not limited to, an expanded metal sheet, a metal plate, a metal frame, a metal mesh structure, and the like.

FIGS. 3B and 3C respectively illustrate side and front views of the compliant fabric 204 attached to the semi-rigid backing 202. The compliant fabric 204 is resistant to the temperatures and conditions that occur within the coating zone 106 during the coating of the substrates 110. Therefore the compliant fabric 204 does not ignite, burn, char or decompose at such temperatures. Moreover, the compliant fabric 204 is vacuum compatible, preferably optically opaque, and possesses a ‘breathable’ character. The vacuum compatibility ensures that any release of gas or vapor from the compliant fabric 204 under vacuum, will not significantly delay or inhibit attainment of vacuum conditions conducive for the coating process. Further, it is also ensured that the gas or vapor does not adversely affect the coating deposited on the substrates. The optical opacity inhibits transmission of the coating precursors through the compliant fabric 204, thereby protecting any surfaces that the compliant fabric 204 covers. The breathable character of the fabric refers to the ability of gas or vapor within the interstices of the compliant fabric 204 to flow freely enough out of the compliant fabric 204 so that attainment of the vacuum conditions is not significantly delayed or inhibited.

Illustratively, the compliant fabric 204 may be a fiberglass fabric. Prior to use in the substrate coating zone 106, the fiberglass fabric is heat-treated. Optionally, the fiberglass fabric may also be pre-coated. For example, the fiberglass fabric may be pre-coated with vermiculite or polytetrafluoroethylene (PTFE). Alternatively, the fiberglass fabric may also be reinforced with wire. Other example materials for the compliant fabric 204 include carbon fiber fabric, ceramic fabric, silica fabric, Kevlar Aramid fabric, metal wool fabric, woven metal wire cloth, and the like. Examples of the ceramic fabric include, but are not limited to, alumina, zirconia and so forth.

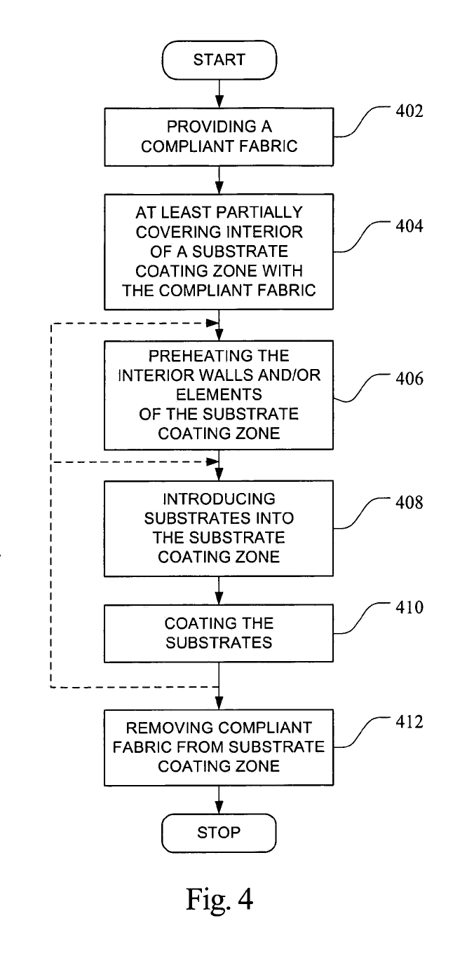

FIG. 4 is a flowchart illustrating one method, embodying the principles of the present invention, for stabilizing a coating on the interior surfaces of the substrate coating zone 106. At step 402, a compliant fabric, such as that described above, is optionally provided so as to define at least one interior surface of the coating zone 106. The compliant fabric 204 may be attached to a semi-rigid backing, such as the semi-rigid backing 202 discussed above. In step 404 the compliant fabric 204 is installed so as to at least partially cover the interior of the substrate coating zone 106 and define one or more interior surfaces thereof. Optionally, the compliant fabric 204 may also be installed so to cover various elements and structures within the substrate coating zone 106.

Prior to the introduction of the substrates 110 into the substrate coating zone 106, at step 406, the interior surfaces of the coating zone 106 are optionally pre-heated to a local preheat temperature. The interior surfaces may be heated by the various means discussed above. After such preheating, the substrates 110 are introduced into the substrate coating zone 106 at step 408, and the deposition of the coating on substrates 110 is performed at step 410.

After coating, the substrates are removed from the substrate coating zone. The process may then be repeated, as a batch coating process denoted by the dashed line extending between steps 404 and 406 and as a continuous coating process denoted by the dashed line extending between steps 406 and 408. Once the incidental coating on the interior surfaces of the substrate coating zone 106 becomes excessive (exhibits stresses that risk ejection of particles of the incidental coating from the interior surfaces), in step 412 the compliant fabric is removed from the substrate coating zone so as to have the incidental coating removed or so as to be replaced. Thereafter, the entire process may be repeated.

As noted above, the incidental coating on the interior surfaces of the substrate coating zone 106 may be stabilized through the preheating of those surfaces, with or without the compliant fabric being used to at least partially define the interior surfaces.

Various embodiments of the present invention provide advantageous methods and apparatuses to inhibit development of undesirably high stresses within an incidental coating during the process of coating a substrate in a substrate coating apparatus. These enable stabilizing the incidental coating on the interior surfaces of the substrate coating apparatus. Consequently, various embodiments of the present invention also inhibit ejection of particles from the incidental coating on the interior surfaces of the substrate coating apparatus. As a result, the various embodiments inhibit or prevent occurrence of surface defects on the substrate. Furthermore, the invention provides the use of a compliant fabric to cover the interior walls of the substrate coating apparatus and form the interior surface of the apparatus. The compliant fabric may be attached to a semi-rigid backing thereby enabling easy removal of the incidental coating and installation of new interior surfaces (via a new compliant fabric) in the substrate coating apparatus.

1. A method for stabilizing a coating on an interior surface of a coating zone in a substrate coating apparatus, the interior surface attaining a local coating temperature during coating of the substrate, the method comprising:
preheating an interior surface of the coating zone to a local preheat temperature, the local preheat temperature being generally equal to the local coating temperature;
after the preheating step, introducing a substrate into the coating zone;
coating the substrate in the coating zone;
forming an incidental coating on the interior surface of the coating zone; and
removing the substrate from the coating zone.

2. The method of claim 1, wherein the step of coating the substrate is a batch coating process.

3. The method of claim 1, wherein the step of coating the substrate is a continuous coating process.

4. The method of claim 1, wherein the forming of the incidental coating occurs on a flexible interior surface of the coating zone.

5. The method of claim 1, wherein the forming of the incidental coating occurs on a permeable interior surface of the coating zone.

6. The method of claim 1, further comprising utilizing a compliant fabric to define at least a portion of the interior surface of the coating zone.

7. The method of claim 1, further comprising providing a compliant fabric over a semi-rigid backing to form a compliant fabric and semi-rigid backing assembly, utilizing the compliant fabric to at least partially define the interior surface of the coating zone.

8. The method of claim 7, further comprising removing and replacing the compliant fabric and semi-rigid backing assembly of the coating zone after forming of the incidental coating thereon.

9. The method of claim 6, wherein the compliant fabric comprises a textured characteristic.

10. The method of claim 6, wherein the compliant fabric comprises fiberglass fabric.

11. The method of claim 10, wherein the fiberglass fabric is pre-coated with vermiculite or polytetrafluoroethylene.

12. The method of claim 10, wherein the fiberglass fabric is reinforced with wire.

13. The method of claim 6, wherein the compliant fabric is selected from the group consisting of carbon fiber fabric, ceramic fabric, silica fabric, Kevlar Aramid fabric, metal wool fabric, and woven metal wire cloth.

14. The method of claim 1, further comprising removing and replacing the interior surface of the coating zone after forming of the incidental coating thereon.

15. A method for stabilizing a coating on an interior surface of a coating zone in a substrate coating apparatus, the interior surface attaining a local coating temperature during coating of the substrate, the method comprising:
at least partially defining the interior surface of the coating zone with a compliant fabric;
introducing a substrate into the coating zone;
coating the substrate in the coating zone;
forming an incidental coating on the interior surface of the coating zone; and
removing the substrate from the coating zone.

16. The method of claim 15 further comprising preheating the interior surfaces to a local preheat temperature that is generally equal to the local coating temperature; and
removing the compliant fabric having the incidental coating thereon from the coating zone.

17. The method of claim 15, wherein the compliant fabric comprises a textured characteristic.

18. The method of claim 15, wherein the compliant fabric comprises fiberglass fabric pre-coated with vermiculite or polytetrafluoroethylene.

19. The method of claim 15, wherein the fiberglass fabric is reinforced with wire.

20. The method of claim 15, wherein the compliant fabric is selected from the group consisting of carbon fiber fabric, ceramic fabric, silica fabric, Kevlar Aramid fabric, metal wool fabric, and woven metal wire cloth.
